(19) United States
(12) Patent Application Publication
(10) Pub. No.: US 2026/0058620 A1
(43) Pub. Date: Feb. 26, 2026

(54) NESTED JFET GAIN STAGE

(71) Applicant: Weed Instrument Company, Inc.

(72) Inventor: Horia Bendea, Cedar Park, TX (US)

(73) Assignee: Weed Instrument Company, Inc., (omitted)

(21) Appl. No.: 19/053,119

(22) Filed: Feb. 13, 2025

Related U.S. Application Data
(60) Provisional application No. 63/686,713, filed on Aug. 23, 2024.

(51) Int. Cl. H03F 3/45

(52) U.S. Cl. CPC H03F 3/45376

(57) ABSTRACT

A junction field effect transistor (JFET) amplifier includes a first JFET gain stage having a first differential input and differential output nodes. The first JFET gain stage further includes matched first and second JFETs having gates coupled to the first differential input and terminals coupled at a common node. The first JFET gain stage also includes a current source coupled to the common node, wherein the current source includes a third JFET. The JFET amplifier further includes a second JFET gain stage having an amplifier output and a second differential input coupled to the differential output nodes.

### BACKGROUND OF THE INVENTION

The present invention relates in general to transistors, and more specifically, to transistor amplifiers. Still more particularly, the present invention relates to junction field effect transistor (JFET) amplifiers.

The JFET is not commonly used in electronic circuits because of several disadvantages in comparison with bipolar junction transistors (BJTs) and metal-oxide-semiconductor field-effect transistors (MOSFETs). JFETs have lower gain than BJTs. JFETs are normal ON devices, which presents a challenge for many power circuits. JFETs are also difficult to manufacture with tight specifications, and their threshold voltages have a large dispersion. Driving a JFET is difficult because the gate voltage often needs to be outside the drain and source voltage range, potentially requiring multiple voltage rails.

### SUMMARY OF THE INVENTION

The present application recognizes, however, that JFETs have significant advantages that make them useful in particular niche applications. For example, JFETs have greater radiation resilience than other types of transistors and are therefore candidates for use in high radiation environments.

In view of the foregoing, the present application presents an architecture for an all-JFET operational amplifier that provides improved accuracy and lower thermal drift when compared with conventional JFET amplifiers. In contrast to some prior art JFET operational amplifiers requiring multiple voltage rails, the disclosed operational amplifier architecture can include a single power supply rail.

In at least some embodiments, a junction field effect transistor (JFET) amplifier includes a first JFET gain stage having a first differential input and differential output nodes. The first JFET gain stage further includes matched first and second JFETs having gates coupled to the first differential input and terminals coupled at a common node. The first JFET gain stage also includes a current source coupled to the common node, wherein the current source includes a third JFET. The JFET amplifier further includes a second JFET gain stage having an amplifier output and a second differential input coupled to the differential output nodes.

In at least some embodiments of a JFET amplifier, the current source includes a voltage divider having a voltage divider node coupled to a gate of the third JFET.

In at least some embodiments of a JFET amplifier, the JFET amplifier further includes matching first and second drain resistors respectively coupled to drains of the first and second JFETs, such that the first and second JFETs have equal drain currents.

In at least some embodiments of a JFET amplifier, the first and second JFETs are configured to operate at approximately equal drain-to-source voltages.

In at least some embodiments of a JFET amplifier, the second JFET gain stage includes matched third and fourth JFETs having gates coupled to the differential output nodes and terminals coupled at a another common node, another current source coupled to the second common node, a third current source coupled to a terminal of the fourth JFET.

In at least some embodiments of a JFET amplifier, the JFET amplifier includes a resistor coupled to another terminal of the third JFET.

### BRIEF DESCRIPTION OF THE DRAWINGS

FIG. 1 is a circuit schematic diagram of an exemplary JFET gain stage in accordance with the prior art; and FIG. 2 is a circuit schematic of an exemplary JFET gain stage in accordance with one or more embodiments.

In accordance with common practice, various features illustrated in the drawings may not be drawn to scale. Accordingly, dimensions of the various features may be arbitrarily expanded or reduced for clarity. In addition, some of the drawings may not depict all of the components of a given system, method, or device. Finally, like reference numerals may be used to denote like or corresponding features in the specification and figures.

### DETAILED DESCRIPTION OF ILLUSTRATIVE EMBODIMENT

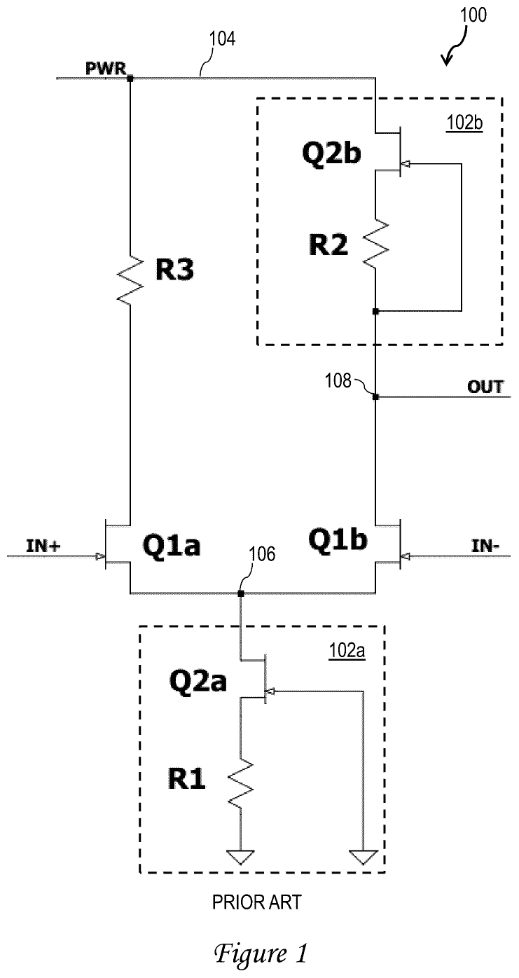

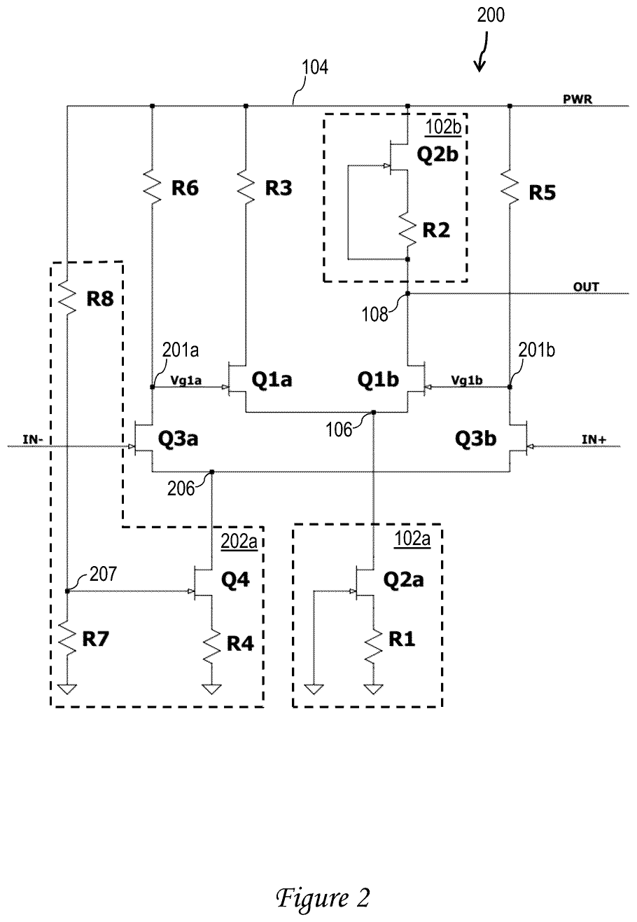

Referring now to FIG. 1, there is illustrated a circuit schematic diagram of an exemplary all Junction Field Effect Transistor (JFET) gain stage 100 in accordance with the prior art. In this example, JFET gain stage 100 includes four JFETs, including a first matched pair of transistors Q1a, Q1b (which serve as input transistors in FIG. 1) and a second matched pair of transistors Q2a, Q2b. Transistor Q2a and resistor R1, which is coupled between ground and the source of transistor Q2a, form a first current source 102a, and transistor Q2b and resistor R2, which is coupled between the source and gate of transistor Q2b, form a second current source 102b. First current source 102a is coupled between ground and a common node 106 coupled to the sources of transistors Q1a and Q1b. Second current source 102b is coupled between a power rail 104 and the drain of transistor Q1b. The node 108 at which the gate of transistor Q2b is coupled to the drain of transistor Q1b serves as an output of JFET gain stage 100.

In first current source 102a, the value of resistor R1 is selected such that first current source 102a will have double the current of the second current source 102b. The current through transistor Q1a is equal to the difference between the currents through transistors Q2a and Q2b. The drain-source currents of transistors Q1a and Q1b are equal. Because matched transistors Q1a and Q1b are operated at the same drain current, the input offset of JFET gain state 100 is very low. Because transistor Q2a is operated at twice the drain current of transistor Q2b, the two current sources 102a, 102b will have different thermal performances. As a result, the currents through transistors Q1a and Q1b change differently with temperature. The drain current imbalance over temperature is perceived as amplifier input offset temperature drift.

Still referring to JFET gain stage 100, a resistor R3 is coupled between power rail 104 and the drain of transistor Q1a. Resistor R3 will initially reduce the drain-to-source voltage of transistor Q1a to a voltage approximately equal with that of transistor Q1b. Because the currents through transistors Q1a and Q1b increase with temperature, the voltage drop across resistor R3 will change significantly with temperature. Thus, transistors Q1a and Q1b will have different drain-to-source voltages, and this drain-to-source voltage difference will change with temperature. This voltage imbalance in turn cause amplifier input offset and offset drift.

Referring now to FIG. 2, there is depicted a circuit schematic of an exemplary all-JFET gain stage 200 (or amplifier) in accordance with one or more embodiments. The illustrated architecture enables the drain currents and drain-to-source voltages of the input transistors to be equal at all temperatures, reducing the amplifier offset and offset temperature drift.

As shown in FIG. 2, the inner (or second) section of the nested gain stage, including transistors Q1a, Q1b, Q2a, and Q2b and resistors R1, R2, and R3, is similar to, and operates in the same way as the simple differential gain stage presented in FIG. 1. Consequently, to promote understanding, similar elements found in JFET gain stage 200 of FIG. 2 labeled with consistent element names and reference characters. In JFET gain stage 200, the difference between the gate voltages of transistors Q1a and Q1b (i.e., Vg1b−Vg1a) is low, for example, in the mV range.

In the schematic diagram of FIG. 2, the inner section of JFET gain stage 200 is wrapped by and coupled to a similar differential outer (or first) section including transistors Q3a, Q3b, and Q4 and resistors R4, R5, R6, R7, and R8. The outer section includes several building blocks similar to those of the inner section.

The outer section of JFET gain stage 200 includes a matched pair of input transistors Q3a and Q3b having respective gates coupled to receive a differential input and sources coupled at a common node 206. The drain of transistor Q3a is coupled by drain resistor R6 to power rail 104, and the drain of transistor Q3b is similarly coupled by drain resistor R4 to power rail 104. The drain of transistor Q3a is coupled at node 201a to supply gate voltage Vg1a to transistor Q1a, and the drain of transistor Q3b is coupled at node 201b to supply gate voltage Vg1b to transistor Q1b. Nodes 201a and 201b form the differential output of the outer section and differential input of the inner section of JFET gain stage 200.

The common node 206 coupling the sources of transistors Q3a and Q3b is further coupled to a low side current source 202a, which in this example is implemented with a transistor Q4 and resistors R4, R7, and R8. Resistors R7 and R8, which are coupled in series between power rail 104 and ground, form a voltage divider. Resistor R4 is coupled between the source of transistor Q4 and ground. Transistor Q4 has its drain coupled to common node 206, its source coupled to resistor R4, and its gate coupled to the voltage divider node 207 between series-connected resistors R7 and R8. Low side current source 202a is made less temperature-dependent by the voltage stability provided by the voltage divider implemented by resistors R7 and R8.

In the depicted embodiment, the drain currents of input transistors Q3a and Q3b are set by low side current source 202a. The current provided by low side current source 202a is equally divided between input transistors Q3a and Q3b because their respective drain resistors R5 and R6 are chosen to be equal and have the same applied voltage, which is equal to the difference between the voltages of power (PWR) rail 104 and the gate voltages (Vg1a and Vg1b) of transistors Q1a and Q1b. The drain-to-source voltages of transistors Q3a and Q3b are also equal because their sources are connected and their drains are at equal voltages Vg1a and Vg1b.

Input transistors Q3a and Q3b are preferably implemented as a matched pair with similar electrical characteristics and good Vgs temperature tracking. Input transistors Q3a and Q3b operate at equal drain currents and equal drain-to-source voltages. As a result of this improved symmetry, nested JFET gain stage 200 has lower input offset and lower offset temperature drift as compared to conventional JFET differential gain stage 100. Additionally, nested JFET gain stage 200 has two cascaded differential stages in series so its overall voltage gain is much higher than the voltage gain of conventional JFET gain stage 100 of FIG. 1. As will be appreciated, JFET gain stage 200 may form a component of a larger electronic system coupled to the differential input and/or to output node 108 of JFET gain stage 200.

As has been described, in at least some embodiments, a junction field effect transistor (JFET) amplifier includes a first JFET gain stage having a first differential input and differential output nodes. The first JFET gain stage further includes matched first and second JFETs having gates coupled to the first differential input and terminals coupled at a common node. The first JFET gain stage also includes a current source coupled to the common node, wherein the current source includes a third JFET. The JFET amplifier further includes a second JFET gain stage having an amplifier output and a second differential input coupled to the differential output nodes.

In at least some embodiments of a JFET amplifier, the current source includes a voltage divider having a voltage divider node coupled to a gate of the third JFET.

In at least some embodiments of a JFET amplifier, the JFET amplifier further includes matching first and second drain resistors respectively coupled to drains of the first and second JFETs, such that the first and second JFETs have equal drain currents.

In at least some embodiments of a JFET amplifier, the first and second JFETs are configured to operate at equal drain-to-source voltages.

In at least some embodiments of a JFET amplifier, the second JFET gain stage includes matched third and fourth JFETs having gates coupled to the differential output nodes and terminals coupled at a another common node, another current source coupled to the second common node, a third current source coupled to a terminal of the fourth JFET.

In at least some embodiments of a JFET amplifier, the JFET amplifier includes a resistor coupled to another terminal of the third JFET.

While the present invention has been particularly shown as described with reference to one or more preferred embodiments, it will be understood by those skilled in the art that various changes in form and detail may be made therein without departing from the spirit and scope of the invention.

The following definitions are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, system or apparatus that comprises a list of elements is not necessarily limited to only those elements but can include other elements not expressly listed or inherent to such composition, mixture, process, method, article, system or apparatus.

Additionally, the term “exemplary” is used herein to mean “serving as one example, instance or illustration. ” Any embodiment or design described herein as “exemplary” is not necessarily to be construed as preferred or advantageous over other embodiments or designs. The terms “at least one” and “one or more” shall be understood to include any integer number greater than or equal to one, and the term “plurality” shall be understood to include any integer number greater than or equal to two. The term “coupled” shall include both indirect connection and a direct connection, unless specified otherwise in a particular case. The terms “about,” “substantially,” “approximately,” and variations thereof, are intended to include the degree of error associated with measurement of the particular quantity based upon the equipment available at the time of filing the application. For example, “approximately” can include a range of ±1% or ±0.5%, or ±0.1% of a given value. The term “equal” as used herein means values within ±0.1%.

The figures described herein and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. For the sake of brevity, conventional techniques related to making and using aspects of the invention(s) may or may not be described in detail herein, and many conventional implementation details are only mentioned briefly or are omitted entirely. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms. Lastly, the use of a singular term, such as, but not limited to, “a” is not intended as limiting of the number of items.

What is claimed is:

1. A junction field effect transistor (JFET) amplifier, comprising:
a first JFET gain stage having a first differential input and differential output nodes, wherein the first JFET gain stage further includes:
matched first and second JFETs having gates coupled to the first differential input and terminals coupled at a common node; and
a current source coupled to the common node, wherein the current source includes a third JFET;
a second JFET gain stage having an amplifier output and a second differential input coupled to the differential output nodes.

2. The junction field effect transistor (JFET) amplifier of claim 1, wherein the current source includes a voltage divider having a voltage divider node coupled to a gate of the third JFET.

3. The junction field effect transistor (JFET) amplifier of claim 1, further comprising matching first and second drain resistors respectively coupled to drains of the first and second JFETs, such that the first and second JFETs have equal drain currents.

4. The junction field effect transistor (JFET) amplifier of claim 1, wherein the first and second JFETs are configured to operate at equal drain-to-source voltages.

5. The junction field effect transistor (JFET) amplifier of claim 1, wherein:
the common node is a first common node;
the current sources is a first current source;
the second JFET gain stage includes:
matched third and fourth JFETs having gates coupled to the differential output nodes and terminals coupled at a second common node;
a second current source coupled to the second common node; and
a third current source coupled to a terminal of the fourth JFET.

6. The junction field effect transistor (JFET) amplifier of claim 5, further comprising:
a resistor coupled to another terminal of the third JFET.

7. A junction field effect transistor (JFET) amplifier, comprising:
a first JFET gain stage having a first differential input and differential output nodes coupled to the second differential input of the second JFET gain stage, wherein the first JFET gain stage further includes:
matched first and second JFETs having gates coupled to the first differential input and terminals coupled at a common node; and
a current source coupled to the common node, wherein the current source includes a third JFET and a voltage divider having a voltage divider node coupled to a gate of the third JFET; and
a second JFET gain stage having an amplifier output and a second differential input coupled to the differential output nodes of the first JFET gain stage.

8. The junction field effect transistor (JFET) amplifier of claim 7, further comprising matching first and second drain resistors respectively coupled to drains of the first and second JFETs, such that the first and second JFETs have equal drain currents.

9. The junction field effect transistor (JFET) amplifier of claim 7, wherein the first and second JFETs are configured to operate at equal drain-to-source voltages.

10. The junction field effect transistor (JFET) amplifier of claim 7, wherein:
the common node is a first common node;
the current sources is a first current source;
the second JFET gain stage includes:
matched third and fourth JFETs having gates coupled to the differential output nodes and terminals coupled at a second common node;
a second current source coupled to the second common node; and
a third current source coupled to a terminal of the fourth JFET.

11. The junction field effect transistor (JFET) amplifier of claim 10, further comprising:
a resistor coupled to another terminal of the third JFET.

12. A junction field effect transistor (JFET) amplifier, comprising:
a first JFET gain stage having a first differential input and differential output nodes, wherein the first JFET gain stage includes:
matched first and second JFETs having gates coupled to the first differential input and terminals coupled at a first common node; and
a first current source coupled to the common node, wherein the first current source includes a third JFET;
a second JFET gain stage having an amplifier output and a second differential input coupled to the differential output nodes of the first JFET gain stage, wherein the second JFET gain stage includes:
matched third and fourth JFETs having gates coupled to the differential output nodes and terminals coupled at a second common node;
a second current source coupled to the second common node; and
a third current source coupled to a terminal of the fourth JFET.

13. The junction field effect transistor (JFET) amplifier of claim 12, wherein the current source includes a voltage divider having a voltage divider node coupled to a gate of the third JFET.

14. The junction field effect transistor (JFET) amplifier of claim 12, further comprising matching first and second drain resistors respectively coupled to drains of the first and second JFETs, such that the first and second JFETs have equal drain currents.

15. The junction field effect transistor (JFET) amplifier of claim 12, wherein the first and second JFETs are configured to operate at equal drain-to-source voltages.

16. The junction field effect transistor (JFET) amplifier of claim 12, further comprising:
a resistor coupled to another terminal of the third JFET.
